(19) United States
(12) Patent Application Publication
(10) Pub. No.: US 2024/0141550 A1
(43) Pub. Date: May 2, 2024

(54) SILICON CARBIDE WAFER MANUFACTURING APPARATUS

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: HIROAKI FUJIBAYASHI, Nisshin-shi (JP); MASATAKE NAGAYA, Nisshin-shi (JP); JUNJI OHARA, Nisshin-shi (JP); SHINICHI HOSHI, Nisshin-shi (JP)

(21) Appl. No.: 18/476,507

(22) Filed: Sep. 28, 2023

(30) Foreign Application Priority Data
Oct. 28, 2022 (JP) 2022-173749

(51) Int. Cl. C30B 25/10; C23C 16/32; C23C 16/458; C23C 16/46; C30B 25/12; C30B 29/36

(52) U.S. Cl. CPC C30B 25/10; C23C 16/325; C23C 16/4584; C23C 16/46; C30B 25/12; C30B 29/36

(57) ABSTRACT

A silicon carbide wafer manufacturing apparatus includes a mounting unit disposed in a reaction chamber. The mounting unit includes a susceptor portion having a mounting surface on which a rear surface of a seed substrate is to be mounted, and a guide portion disposed on the susceptor portion in a state of surrounding the seed substrate. The mounting unit is configured such that a first interval between the seed substrate and the guide portion on an upstream side in a step-flow growth direction is narrower than a second interval between the seed substrate and the guide portion on a downstream side in the step-flow growth direction when an epitaxial layer is grown. The guide portion is configured such that a temperature of the guide portion is lower than a temperature of the seed substrate when the epitaxial layer is grown.

### CROSS REFERENCE TO RELATED APPLICATION

The present application claims the benefit of priority from Japanese Patent Application No. 2022-173749 filed on Oct. 28, 2022. The entire disclosure of the above application is incorporated herein by reference.

### TECHNICAL FIELD

The present disclosure relates to a silicon carbide (SiC) wafer manufacturing apparatus.

### BACKGROUND

Conventionally, it has been proposed to form a SiC wafer by growing an epitaxial layer on a seed substrate composed of SiC and having an off angle. It has also been reported that when an epitaxial layer is grown on a seed substrate composed of SiC, the epitaxial layer is subjected to a step-flow growth. Furthermore, it has been reported that when an epitaxial layer is grown on a seed substrate having an off angle, defects including unevenness are likely to occur on an upstream side in a step-flow growth direction.

### SUMMARY

The present disclosure provides a silicon carbide wafer manufacturing apparatus including a mounting unit disposed in a reaction chamber. The mounting unit includes a susceptor portion having a mounting surface on which a rear surface of a seed substrate is to be mounted, and a guide portion disposed on the susceptor portion in a state of surrounding the seed substrate. The mounting unit is configured such that a first interval between the seed substrate and the guide portion on an upstream side in a step-flow growth direction becomes narrower than a second interval between the seed substrate and the guide portion on a downstream side in the step-flow growth direction when an epitaxial layer is grown. The guide portion is configured such that a temperature of the guide portion becomes lower than a temperature of the seed substrate when the epitaxial layer is grown.

### BRIEF DESCRIPTION OF DRAWINGS

Objects, features and advantages of the present disclosure will become apparent from the following detailed description made with reference to the accompanying drawings. In the drawings:

FIG. 1 is a schematic view illustrating a SiC wafer manufacturing apparatus according to a first embodiment;

FIG. 2 is a diagram illustrating the relationship between the surface roughness and the emissivity of SiC;

FIG. 3 is a schematic view of the vicinity of a seed substrate when an epitaxial layer is grown;

FIG. 4 is a schematic view of the vicinity of the seed substrate after the epitaxial layer is grown;

FIG. 5 is a diagram illustrating conditions for growing the epitaxial layer;

FIG. 6 is a graph showing the relationship between the distance from the center of the seed substrate, the growth rate, and the heat flux;

FIG. 7 is a plan view of a SiC wafer;

FIG. 8 is a diagram obtained by binarizing an optical micrograph of a region A in FIG. 7 in a case where a first interval is set to 0.0 mm;

FIG. 9 is a diagram obtained by binarizing an optical micrograph of the region A in FIG. 7 in a case where the first interval is set to 1.5 mm;

FIG. 10 is a diagram obtained by binarizing an optical micrograph of the region A in FIG. 7 in a case where the first interval is set to 3.0 mm;

FIG. 11 is a diagram illustrating the relationship between the distance from a center of the SiC wafer and the level difference;

FIG. 12 is a diagram illustrating the relationship between the distance and the level difference;

FIG. 13 is a plan view illustrating a state before rotation when the seed substrate is mounted on a mounting unit;

FIG. 14 is a cross-sectional view taken along line XIV-XIV in FIG. 13;

FIG. 15 is a plan view illustrating a state during rotation when the seed substrate is mounted on the mounting unit;

FIG. 16 is a cross-sectional view taken along line XVI-XVI in FIG. 15;

FIG. 17 is a plan view illustrating a state during rotation when a seed substrate is disposed on a mounting unit in a third embodiment; and

FIG. 18 is a cross-sectional view taken along line XVIII-XVIII in FIG. 17.

### DETAILED DESCRIPTION

In a case where defects including an uneven portion occur in a SiC wafer and a semiconductor element such as a metal oxide semiconductor field effect transistor (MOSFET) is formed using the SiC wafer including the defects as it is, there is a possibility that stress is concentrated on the uneven portion during heat treatment and the SiC wafer is cracked. In addition, in a case where a process of disposing a resist on the SiC wafer is included in a forming process of the semiconductor element, the resist is likely to remain in the uneven portion when the resist is peeled off, and there is a possibility that the resist becomes a foreign substance.

Therefore, for example, it is conceivable to form a SiC wafer by growing an epitaxial layer on a seed substrate, and then remove a portion of the SiC wafer located on an upstream side in a step-flow growth direction. That is, after the SiC wafer is formed by growing the epitaxial layer on the seed substrate, a portion where defects are likely to be formed may be removed. Then, by forming a semiconductor element using the SiC wafer from which the portion on the upstream side has been removed, it is possible to restrict cracking of the SiC wafer and inclusion of foreign substances in the manufactured SiC semiconductor device.

However, removing the portion of the SiC wafer located on the upstream side in the step-flow growth direction requires a process different from the process of manufacturing the SiC wafer, and the number of manufacturing processes is likely to increase.

A silicon carbide wafer manufacturing apparatus according to an aspect of the present disclosure includes a reaction chamber forming portion, a reactant gas supply pipe, a mounting unit, a rotating device, and a heating device. The reaction chamber forming portion is configured to form a reaction chamber for step-flow growth of an epitaxial layer on a front surface of a seed substrate. The epitaxial layer is composed of silicon carbide. The seed substrate is composed of silicon carbide and has an off angle. The reactant gas supply pipe is communicated with the reaction chamber and is configured to supply a reactant gas for growing the epitaxial layer to the reaction chamber. The mounting unit is disposed in the reaction chamber and the seed substrate is to be mounted on the mounting unit. The rotating device has a cylindrical portion on which the mounting unit is disposed on one end side and is configured to rotate the mounting unit together with the seed substrate. The heating device is configured to heat the seed substrate. The mounting unit includes a susceptor portion having a mounting surface on which a rear surface of the seed substrate is to be mounted, and a guide portion disposed on the susceptor portion in a state of surrounding the seed substrate. The mounting unit is configured such that a first interval between the seed substrate and the guide portion on an upstream side in a step-flow growth direction becomes narrower than a second interval between the seed substrate and the guide portion on a downstream side in the step-flow growth direction when the epitaxial layer is grown. The guide portion is configured such that a temperature of the guide portion becomes lower than a temperature of the seed substrate when the epitaxial layer is grown.

According to this configuration, when the epitaxial layer is grown, the temperature of the guide portion becomes lower than the temperature of the seed substrate. Furthermore, when the epitaxial layer is grown, the first interval between the seed substrate and the guide portion on the upstream side in the step-flow growth direction becomes narrower than the second interval between the seed substrate and the guide portion on the downstream side in the step-flow growth direction. Therefore, when the epitaxial layer is grown, the epitaxial layer is difficult to grow on the upstream side in the growth direction in which defects are likely to occur. Therefore, unevenness is less likely to be included in the SiC wafer, and the SiC wafer can be directly used for manufacturing a semiconductor element without performing a process of removing a portion on the upstream side in the growth direction.

The following describes embodiments of the present disclosure with reference to the drawings. In the following embodiments, the same or equivalent parts are denoted by the same reference numerals for description.

### First Embodiment

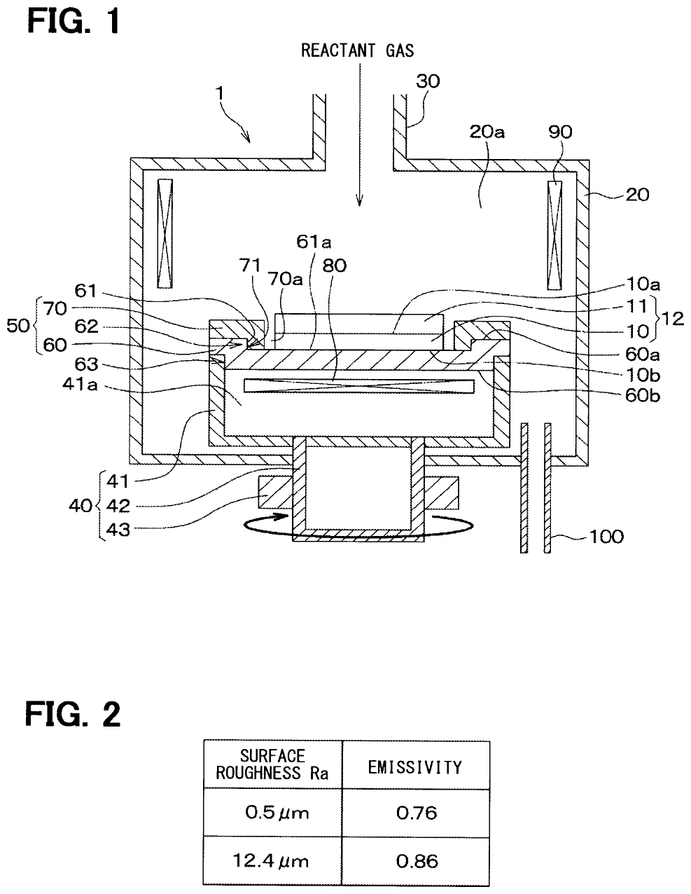

The following describes a first embodiment with reference to the drawings. As shown in FIG. 1, a SiC wafer manufacturing apparatus (hereinafter, also simply referred to as a manufacturing apparatus) 1 includes a chamber 20 that forms a reaction chamber 20a in which an epitaxial layer 11 as a semiconductor layer is grown on a front surface 10a of a seed substrate 10 to manufacture a SiC wafer 12. In the present embodiment, the chamber 20 corresponds to a reaction chamber forming member that forms the reaction chamber 20a.

A reactant gas supply pipe 30 configured to supply a reactant gas for growing a crystal thin film on the front surface 10a of the seed substrate 10 is provided on an upper side of the chamber 20. In the present embodiment, in order to epitaxially grow SiC, the reactant gas includes, for example, a source gas including silane (SiH₄) and propane (C₃H₈), and a carrier gas including hydrogen and hydrogen chloride (HCl).

Specifically, the reactant gas supply pipe 30 is disposed on the upper side of the chamber 20 so that a position facing the front surface 10a of the seed substrate 10 is opened. Accordingly, the reactant gas is supplied to the reaction chamber 20a from a direction intersecting the front surface 10a of the seed substrate 10 (that is, a direction substantially perpendicular to the front surface 10a) toward the front surface 10a of the seed substrate 10. Therefore, it can be said that the manufacturing apparatus 1 of the present embodiment has a downflow-type gas supply structure in which the reactant gas is blown down toward the front surface 10a of the seed substrate 10.

Furthermore, a rotating device 40 to which the seed substrate 10 is mounted is disposed on a lower side of the reaction chamber 20a. In the present embodiment, the seed substrate 10 is mounted on a mounting unit 50 disposed on the rotating device 40.

The rotating device 40 includes a cylindrical member 41, a rotating shaft 42, a driving unit 43, and the like. The cylindrical member 41 is a member having a bottomed cylindrical shape and forms a hollow chamber 41a, and the mounting unit 50 is disposed at an opening end portion. The cylindrical member 41 is disposed such that the opening end portion faces the upper side of the chamber 20 (that is, the side of the reactant gas supply pipe 30).

The rotating shaft 42 is a shaft that is rotated by an output of the driving unit 43, and is connected to the cylindrical member 41 so as to be rotatable integrally with the cylindrical member 41. The driving unit 43 includes a motor or the like that outputs a rotational force, and rotates the rotating shaft 42. In the rotating device 40 configured as described above, the rotating shaft 42 is rotated by the output of the driving unit 43, and the cylindrical member 41 and the mounting unit 50 are integrally rotated.

The mounting unit 50 is configured to include a susceptor portion 60 and a guide portion 70. The susceptor portion 60 has an outer shape corresponding to the opening end portion of the cylindrical member 41, and substantially closes the cylindrical member 41 by being disposed at the opening end portion of the cylindrical member 41. Accordingly, the hollow chamber 41a of the cylindrical member 41 is substantially closed.

Specifically, the susceptor portion 60 has a plate shape having a first surface 60a and a second surface 60b, and has a recessed portion 61 for accommodating the seed substrate 10 in a central portion close to the first surface 60a. Thus, the susceptor portion 60 has a step portion 62 at a boundary between the first surface 60a and the recessed portion 61. The recessed portion 61 is formed such that a position of the center of the recessed portion 61 coincides with a position of a central axis of the rotating shaft 42 when the susceptor portion 60 is disposed in the rotating device 40.

The susceptor portion 60 further has a step portion 63 for fitting with the opening end portion of the cylindrical member 41 at an outer edge portion close to the second surface 60b. The susceptor portion 60 is disposed in the cylindrical member 41 by fitting the step portion 63 into the opening end portion of the cylindrical member 41.

The guide portion 70 has a cylindrical shape matching the shape of the outer edge portion of the susceptor portion 60, and a step portion 71 is provided at one end portion. The guide portion 70 is disposed on the susceptor portion 60 by fitting the step portion 71 into the step portion 62 of the susceptor portion 60.

Here, the guide portion 70 of the present embodiment is configured to have a higher emissivity than the seed substrate 10. According to the study by the present inventors, as shown in FIG. 2, it was confirmed that the emissivity of SiC increases with increase in surface roughness Ra of SiC. Therefore, in the present embodiment, the guide portion 70 is composed of SiC and has a surface roughness Ra larger than the surface roughness Ra of the seed substrate 10. In order to increase the surface roughness Ra of the guide portion 70, for example, the surface roughness Ra may be increased by adjusting a processing tool that is used when an SiC ingot is processed to form the guide portion 70. In order to increase the surface roughness Ra of the guide portion 70, for example, the surface roughness Ra may be increased by performing a blast treatment or the like after processing. The guide portion 70 of the present embodiment may be composed of a material different from SiC as long as the emissivity is higher than that of the seed substrate 10, and may be composed of, for example, carbide or the like.

The seed substrate 10 is mounted on the mounting unit 50 such that a bottom surface 61a of the recessed portion 61 of the susceptor portion 60 serves as a mounting surface and a rear surface 10b of the seed substrate 10 faces the bottom surface 61a. In the present embodiment, the guide portion 70 is configured as described above. Therefore, it can be said that the seed substrate 10 is disposed in a space 70a in the guide portion 70.

In the hollow chamber 41a, a first heater 80 as a heating device for heating the seed substrate 10 from a direction close to the rear surface 10b is disposed. As the first heater 80, for example, a resistance heating heater made of carbon is used. Although not illustrated, the first heater 80 is connected to a controller or the like and is heated to a predetermined temperature. In the present embodiment, the first heater 80 corresponds to a first heating device.

In the chamber 20, a second heater 90 is disposed above the rotating device 40. The second heater 90 is a heating device that heats the seed substrate 10 from a direction close to the front surface 10a. As the second heater 90, for example, a resistance heating heater made of carbon is used. Although not illustrated, the second heater 90 is connected to a controller or the like and is heated to a predetermined temperature. For example, the second heater 90 is annularly disposed along an inner wall surface of the chamber 20. In the present embodiment, the second heater 90 corresponds to a second heating device.

As will be specifically described later, the first heater 80 and the second heater 90 of the present embodiment are driven in such a manner that a temperature of the hollow chamber 41a becomes higher than a temperature of the reaction chamber 20a. In other words, the first heater 80 and the second heater 90 are driven in such a manner that the temperature of the rear surface 10b of the seed substrate 10 becomes higher than the temperature of the front surface 10a.

On the lower side of the chamber 20, a reactant gas discharge pipe 100 for discharging a gas after reaction or an unreacted gas is provided. A portion of the reactant gas discharge pipe 100 on a side opposite to the chamber 20 is connected to a vacuum pump (not shown). Accordingly, the reaction chamber 20a is maintained at a predetermined pressure.

Note that, although not particularly illustrated, a lifting device is disposed in the hollow chamber 41a. The lifting device assists, for example, loading of the mounting unit 50 mounted with the seed substrate 10 into the reaction chamber 20a and unloading of the mounting unit 50 from the reaction chamber 20a by a transfer robot. For example, the lifting device has a function of transferring the mounting unit 50 to the transfer robot by raising the mounting unit 50 and separating the mounting unit from the cylindrical member 41. However, the manufacturing apparatus 1 does not have to perform loading and unloading of the mounting unit 50 mounted with the seed substrate 10 and may be configured to perform loading and unloading of only the seed substrate 10 without moving the mounting unit 50.

The above is the configuration of the manufacturing apparatus 1 according to the present embodiment. Next, a method of growing the epitaxial layer 11 on the front surface 10a of the seed substrate 10 using the above-described manufacturing apparatus 1 will be described.

First, in the manufacturing apparatus 1, the reaction chamber 20a is heated to about 1600 to 1750° C. by the first heater 80 and the second heater 90 while the mounting unit 50 mounted with the seed substrate 10 is rotated at, for example, 200 rpm by the rotating device 40. Then, the reactant gas is supplied from the reactant gas supply pipe 30 toward the reaction chamber 20a. As a result, the silane gas and the propane gas contained in the reactant gas react with each other, and the epitaxial layer 11 composed of SiC is grown in a step-flow manner on the seed substrate 10, whereby the SiC wafer 12 is manufactured.

However, in the present embodiment, specifically, the epitaxial layer 11 is grown as follows. First, the seed substrate 10 is composed of SiC, and for example, 4H-SiC having an off angle of 0 to 8° with respect to a (0001) Si plane is used. The seed substrate 10 is not limited thereto, and may be composed of 6H-SiC or 3C-SiC, and the detailed value of the off angle can be appropriately changed.

In the present embodiment, when the reaction chamber 20a and the hollow chamber 41 are heated by the first heater 80 and the second heater 90, the temperature of the rear surface 10b of the seed substrate 10 becomes higher than the temperature of the front surface 10a. Specifically, the first heater 80 and the second heater 90 are driven in such a manner that the temperature of the hollow chamber 41a becomes higher than the temperature of the reaction chamber 20a. In the present embodiment, as described above, the emissivity of the guide portion 70 is set to be higher than the emissivity of the seed substrate 10. Therefore, the guide portion 70 having the high emissivity radiates more heat than the seed substrate 10, and the temperature of the guide portion 70 becomes lower than the temperature of the seed substrate 10.

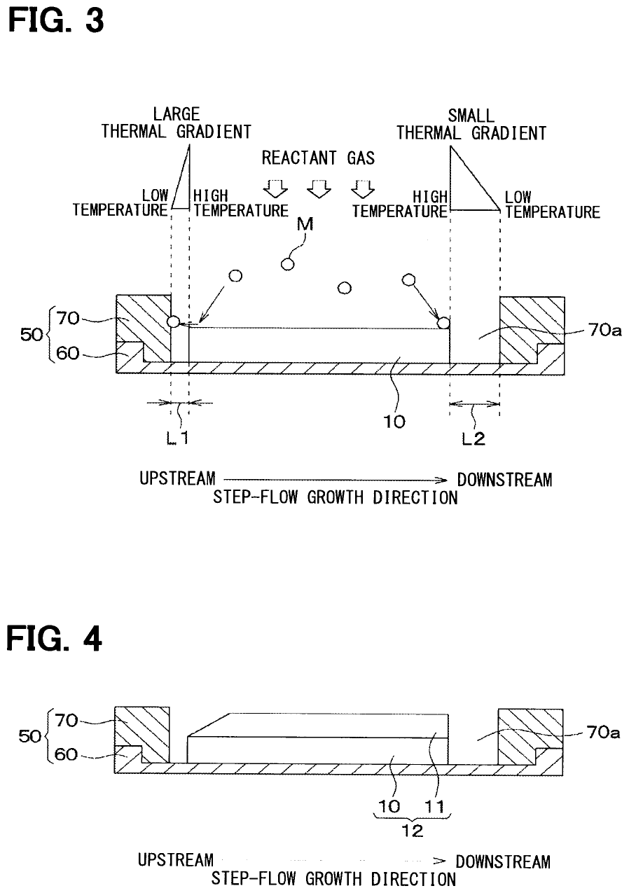

Furthermore, in the present embodiment, as shown in FIG. 3, the epitaxial layer 11 is grown on the seed substrate 10 in a state where the following relationship is satisfied in a step-flow growth direction (hereinafter, also simply referred to as a growth direction). That is, the epitaxial layer 11 is grown on the seed substrate 10 in a state where a first interval L1 between the seed substrate 10 and the guide portion 70 on an upstream side in the growth direction is narrower than a second interval L2 between the seed substrate 10 and the guide portion 70 on a downstream side in the growth direction.

As a result, a temperature gradient of a portion at the first interval L1 is larger than a temperature gradient of a portion at the second interval L2, so that raw material species M contained in the reactant gas likely to flow toward the guide portion 70 on the upstream side in the growth direction. Therefore, as shown in FIG. 4, the epitaxial layer 11 is less likely to grow on the upstream side of the seed substrate 10 in the growth direction. That is, when the epitaxial layer 11 is grown, the epitaxial layer is less likely to grow on the upstream side in the growth direction in which defects such as unevenness are likely to be formed.

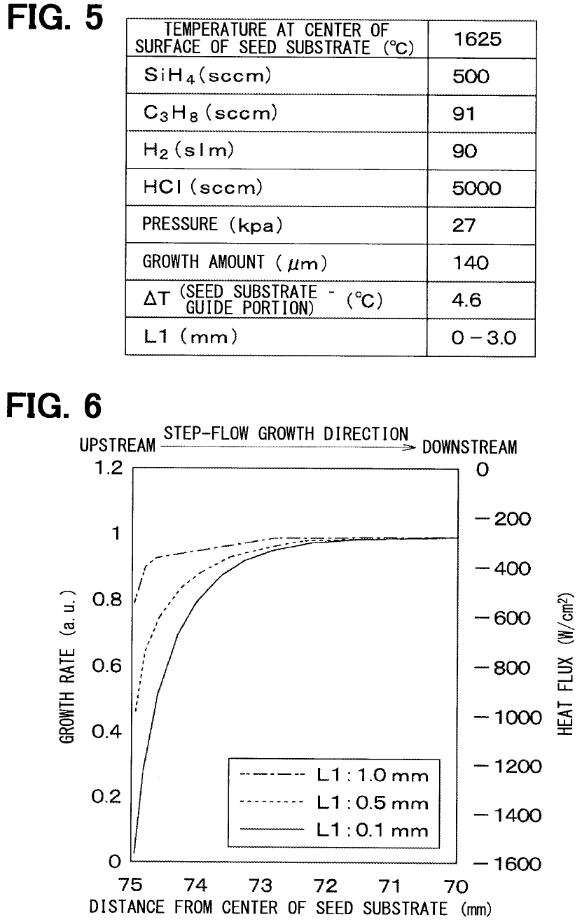

The present inventors performed a simulation of growing the epitaxial layer 11 under the conditions shown in FIG. 5, and obtained the results shown in FIG. 6. As shown in FIG. 5, the conditions for growing the epitaxial layer 11 are such that the temperature at the center of the front surface 10a of the seed substrate 10 is 1625° C., the flow rate of silane is 500 sccm, the flow rate of propane is 91 sccm, the flow rate of hydrogen is 90 sccm, and the flow rate of hydrogen chloride is 5000 sccm. The pressure in the chamber 20 is set to 27 kPa, and the growth amount of the epitaxial layer 11 is set to 140 μm. A temperature difference ΔT between the seed substrate 10 and the guide portion 70 is set to 4.6° C., and the first interval L1 is changed between 0 to 3.0 mm.

As shown in FIG. 6, it is confirmed that since the raw material species M are more likely to flow toward the guide portion 70 with decrease in the first interval L1 on the upstream side in the growth direction, the growth rate of the epitaxial layer 11 decreases with decrease in the first interval L1. In addition, it is confirmed that the magnitude of a heat flux toward the epitaxial layer 11 increases with decrease in the first interval L1 on the upstream side in the growth direction. Note that FIG. 6 shows a distance from the center of the seed substrate 10 in the plane direction. Since a six-inch substrate is used in this simulation, 75 mm is the end of the seed substrate 10. In FIG. 6, the heat flux from the seed substrate 10 toward the epitaxial layer 11 is shown as negative, and the magnitude of the heat flux corresponds to the magnitude of the temperature gradient. That is, it is confirmed from FIG. 6 that the temperature gradient increases with decrease in the first interval L1.

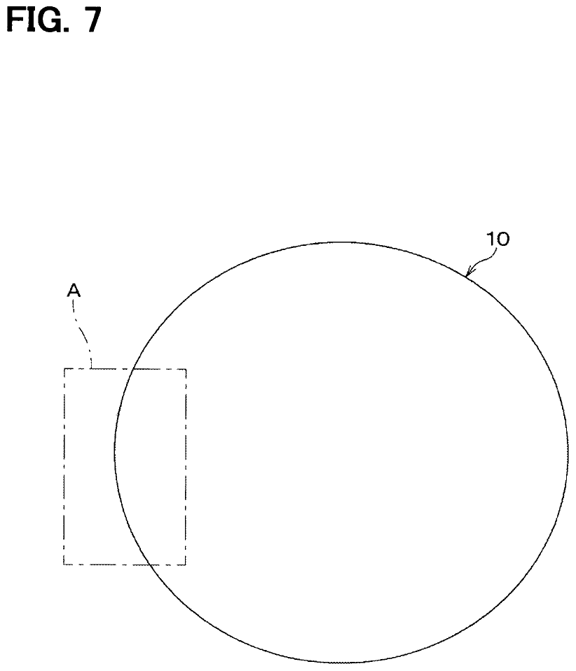

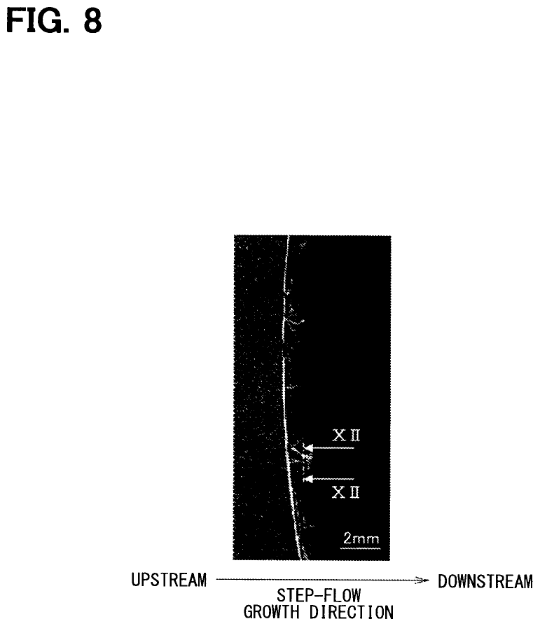

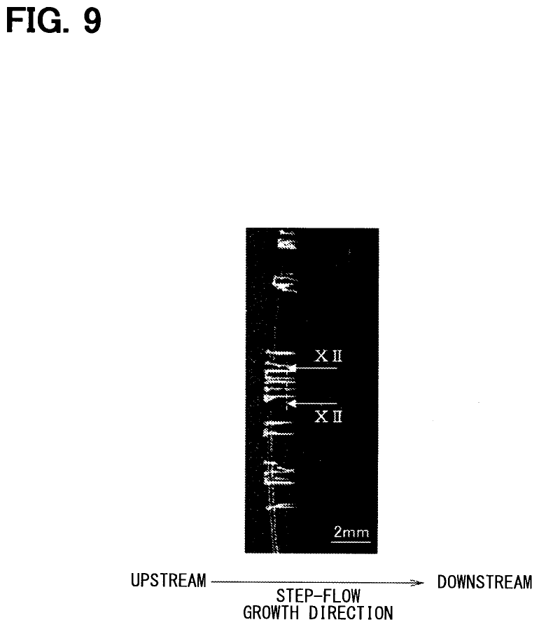

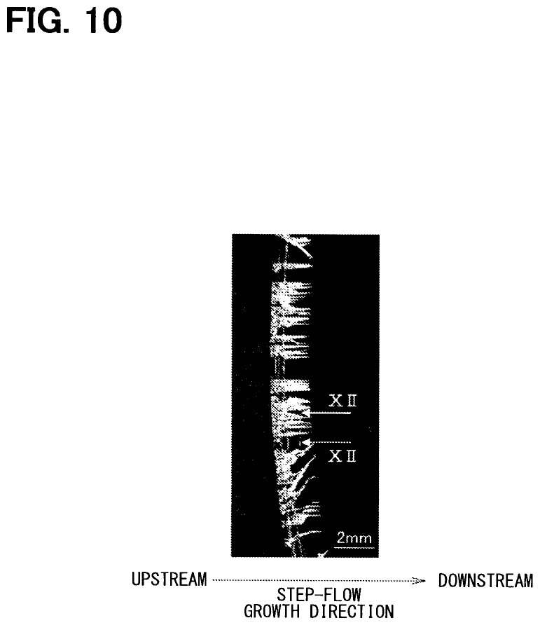

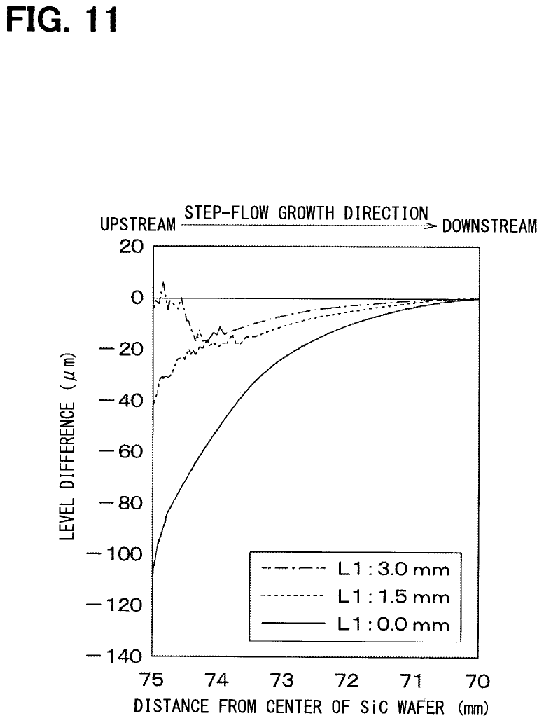

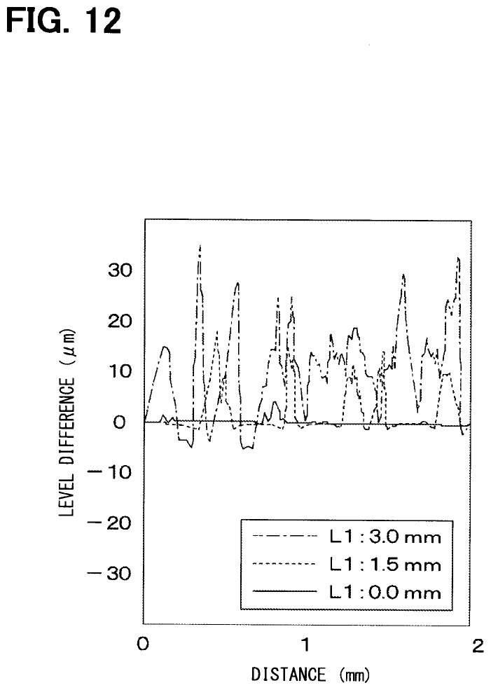

Then, when the present inventors actually grown the epitaxial layer 11 on the seed substrate 10, the results shown in FIGS. 8 to 12 were obtained. FIGS. 8 to 12 show results obtained when the epitaxial layer 11 is grown under the conditions shown in FIG. 5. FIGS. 8 to 10 are diagrams obtained by binarizing the results obtained by an optical microscope for a region A located on the upstream side in the growth direction in the SiC wafer 12 subjected to the step-flow growth as shown in FIG. 7. FIG. 8 is a diagram showing the result in a case where the first interval L1 is set to 0.0 mm, FIG. 9 is a diagram showing the result in a case where the first interval L1 is set to 1.5 mm, and FIG. 10 is a diagram showing the result in a case where the first interval L1 is set to 3.0 mm. FIG. 11 shows level differences with a position 70 mm away from the center of the SiC wafer 12 as a reference (that is, level difference 0). In FIG. 12, both ends in a portion along the XII-XII line in FIGS. 8 to 10 (that is, positions at distances of 0 mm and 2 mm) are set as a reference (that is, level difference 0). In FIG. 11 and FIG. 12, the first interval L1 of 0.0 mm indicates a state in which the seed substrate 10 and the guide portion 70 are in contact with each other. In FIG. 11 and FIG. 12, the first interval L1 of 1.5 mm indicates a state in which the first interval L1 and the second interval L2 are equal to each other, and the first interval L1 of 3.0 mm indicates a state in which the first interval L1 is wider than the second interval L2.

As shown in FIGS. 8 to 10, it is confirmed that defects including unevenness are less likely to occur with decrease in the first interval L1. As shown in FIG. 11 and FIG. 12, it is confirmed that the unevenness decreases with decrease in the first interval L1, and almost no unevenness is formed in the case where the first interval L1 is 0.0 mm.

Therefore, in the present embodiment, the first interval L1 is set to be narrower than the second interval L2. Specifically, in the present embodiment, in order to make the first interval L1 narrower than the second interval L2, the epitaxial layer 11 is grown on the seed substrate 10 as follows.

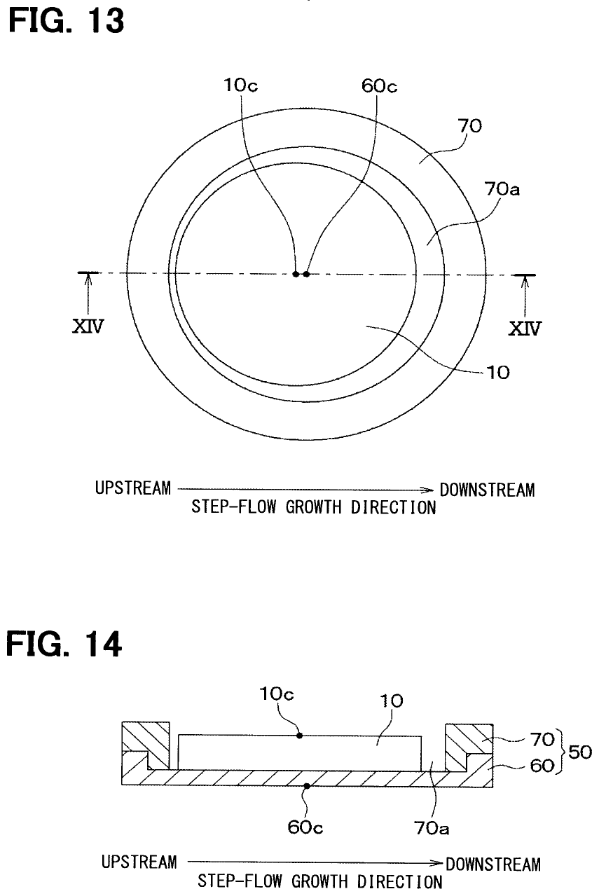

That is, in the present embodiment, as shown in FIG. 13 and FIG. 14, the bottom surface of the recessed portion 61 of the susceptor portion 60 is formed into a perfect circle. A position of the center of the recessed portion 61 coincides with a position of a center 60c of the susceptor portion 60 (that is, the central axis of the rotation shaft 42) when viewed in the normal direction to the plane direction of the bottom surface 61a of the susceptor portion 60 (hereinafter, also simply referred to as the normal direction). Then, a center 10c of the seed substrate 10 is disposed so as to be positioned upstream of the center 60c of the susceptor portion 60 in the growth direction.

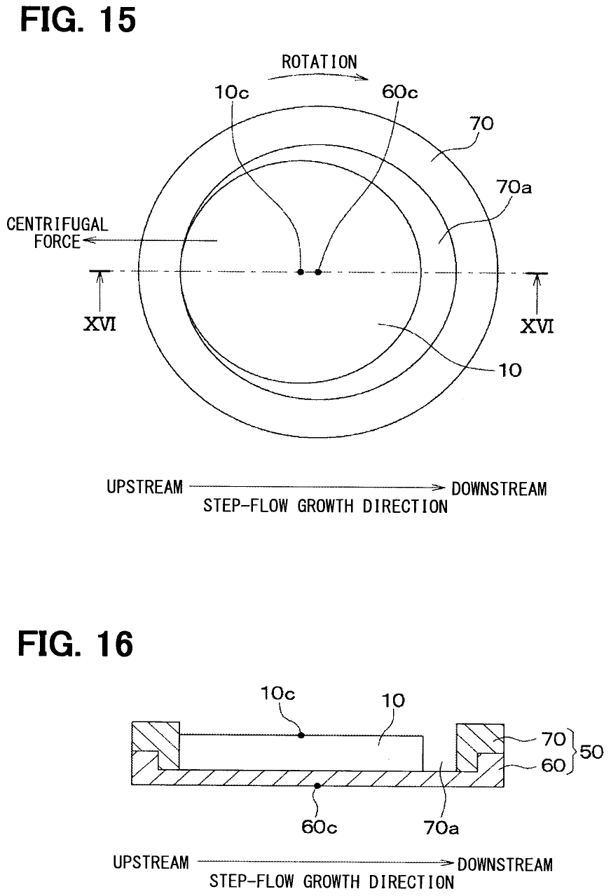

Thereafter, the rotating shaft 42 is rotated in this state to grow the epitaxial layer 11 on the seed substrate 10. At this time, as shown in FIG. 15 and FIG. 16, since the center 10c of the seed substrate 10 is disposed so as to be positioned upstream of the center 60c of the susceptor portion 60 in the growth direction, the seed substrate 10 is displaced upstream in the growth direction by the centrifugal force due to the rotation of the susceptor portion 60 and comes into contact with the guide portion 70. That is, the first interval L1 becomes 0.0 mm. Therefore, the epitaxial layer 11 can be grown on the seed substrate 10 in a state where the first interval L1 is narrower than the second interval L2. FIG. 8 shows the result in a case where the first interval L1 was set to 0.0 mm by this method.

According to the present embodiment described above, the temperature of the guide portion 70 is set to be lower than that of the seed substrate 10 when the epitaxial layer 11 is grown. When the epitaxial layer 11 is grown, the first interval L1 between the seed substrate 10 and the guide portion 70 on the upstream side is set to be narrower than the second interval L2 between the seed substrate 10 and the guide portion 70 on the downstream side in the growth direction. Accordingly, when the epitaxial layer 11 is grown, the epitaxial layer 11 is less likely to grow on the upstream side in the growth direction in which defects are likely to occur. Therefore, unevenness is less likely to be included in the SiC wafer 12, and the SiC wafer 12 can be directly used for manufacturing a semiconductor element without performing a process of removing a portion of the SiC wafer 12 on the upstream side in the growth direction.

In the present embodiment, the second interval L2 is wider than the first interval L1. Therefore, when the epitaxial layer 11 is grown, it is possible to restrict the epitaxial layer 11 from becoming difficult to grow on the downstream side in the growth direction. Therefore, the epitaxial layer 11 having good crystal quality can be grown on the downstream side of the SiC wafer 12 in the growth direction.

In the present embodiment, the reaction chamber 20a is heated using the first heater 80 and the second heater 90. Therefore, it is possible to easily adjust the magnitude of the temperature gradient of the portion at the first interval L1 and the magnitude of the temperature gradient of the portion at the second interval L2.

In the present embodiment, by adjusting the position when the seed substrate 10 is disposed in the susceptor portion 60, the first interval L1 can be set to 0.0 mm when the epitaxial layer 11 is grown. Therefore, there is no need for a special configuration for setting the first interval L1 to 0.0 mm when the epitaxial layer 11 is grown, and it possible to restrict the manufacturing apparatus 1 from becoming complicated.

### Second Embodiment

The following describes a second embodiment. The present embodiment is different from the first embodiment in the configuration of the guide portion 70. The other configurations of the present embodiment are similar to those of the first embodiment, and therefore a description of the similar configurations will not be repeated.

The basic configuration of the manufacturing apparatus 1 of the present embodiment is similar to that of the first embodiment. However, in the present embodiment, the emissivity of the guide portion 70 is lower than the emissivity of the seed substrate 10. For example, the guide portion 70 is composed of SiC and has a surface roughness Ra smaller than the surface roughness Ra of the seed substrate 10.

In the present embodiment, when the epitaxial layer 11 is grown on the seed substrate 10, the first heater 80 and the second heater 90 are driven in such a manner that the temperature of the front surface 10a of the seed substrate 10 becomes higher than the temperature of the rear surface 10b. That is, the temperature of the hollow chamber 41a is set to be lower than the temperature of the reaction chamber 20a. Accordingly, in the present embodiment, when the epitaxial layer 11 is grown, the seed substrate 10 absorbs more heat than the guide portion 70, and the seed substrate 10 has a higher temperature than the guide portion 70. That is, the temperature of the guide portion 70 is lower than the temperature of the seed substrate 10. Therefore, by making the first interval L1 narrower than the second interval L2 as in the first embodiment, it is possible to restrict the epitaxial layer 11 from growing on the upstream side in the growth direction.

As in the present embodiment described above, the emissivity of the guide portion 70 may be lower than the emissivity of the seed substrate 10. Even in such a configuration, it is possible to obtain effects similar to the effects of the first embodiment by adjusting the first heater 80 and the second heater 90 in such a manner that the temperature of the front surface 10a of the seed substrate 10 becomes higher than the temperature of the rear surface 10b, and by making the first interval L1 narrower than the second interval L2.

### Third Embodiment

The following describes a third embodiment. The present embodiment is different from the first embodiment in the configuration of the guide portion 70. The other configurations of the present embodiment are similar to those of the first embodiment, and therefore a description of the similar configurations will not be repeated.

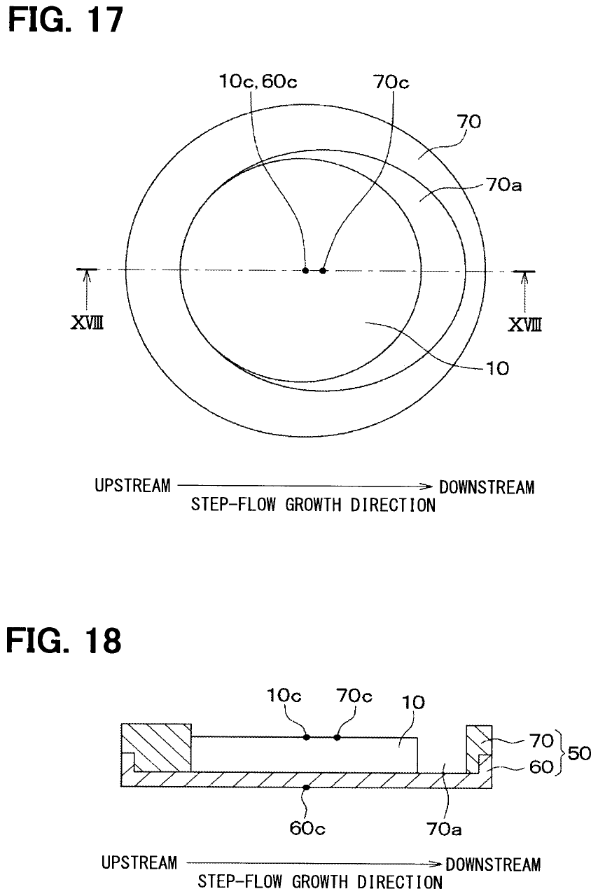

In the manufacturing apparatus 1 of the present embodiment, as shown in FIG. 17 and FIG. 18, the guide portion 70 has a portion whose thickness changes in a circumferential direction so that a center 70c of the space 70a in the guide portion 70 is located downstream of the center 60c of the susceptor portion 60 in the growth direction. Then, the seed substrate 10 is disposed so that the center 10c coincides with the center 60c of the susceptor portion 60, and the seed substrate 10 comes into contact with the guide portion 70 located on the upstream side in the growth direction. A change in the thickness of the guide portion 70 means a change in the length between an inner wall surface and an outer wall surface of the guide portion 70.

According to the present embodiment described above, when the epitaxial layer 11 is grown, the temperature of the guide portion 70 is lower than the temperature of the seed substrate 10, and the first interval L1 is narrower than the second interval L2. Therefore, effects similar to the effects of the first embodiment can be obtained.

As in the present embodiment, the interval between the first interval L1 and the second interval L2 may be adjusted by adjusting the shape of the guide portion 70. In this case, by configuring the guide portion 70 to be separable from the susceptor portion 60, the shape of the guide portion 70 can be easily adjusted.

### Other Embodiments

Although the present disclosure has been described in accordance with the embodiments, it is understood that the present disclosure is not limited to such embodiments or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

For example, in each of the above embodiments, an example in which the first interval L1 is 0.0 mm when the epitaxial layer 11 is grown has been described. However, if the first interval L1 is narrower than the second interval L2, the first interval L1 may be other than 0.0 mm. For example, a support pin or the like may be disposed on the bottom surface 61a of the susceptor portion 60 so that the first interval L1 does not become 0.0 mm when the mounting unit 50 is rotated.

In each of the above embodiments, the susceptor portion 60 and the guide portion 70 may be integrated.

Furthermore, in the first embodiment, the second heater 90 may be omitted. Similarly, in the second embodiment, the first heater 80 may be omitted.

The embodiments described above can also be combined with each other. For example, the first interval L1 and the second interval L2 may be adjusted by combining the second embodiment with the third embodiment and adjusting the shape of the guide portion 70.

What is claimed is:

1. A silicon carbide wafer manufacturing apparatus comprising:
a reaction chamber forming portion configured to form a reaction chamber for step-flow growth of an epitaxial layer on a front surface of a seed substrate, the epitaxial layer being composed of silicon carbide, the seed substrate being composed of silicon carbide and having an off angle;
a reactant gas supply pipe communicated with the reaction chamber and configured to supply a reactant gas for growing the epitaxial layer to the reaction chamber;
a mounting unit disposed in the reaction chamber and on which the seed substrate is to be mounted;
a rotating device having a cylindrical portion on which the mounting unit is disposed on one end side and configured to rotate the mounting unit together with the seed substrate; and
a heating device configured to heat the seed substrate, wherein
the mounting unit includes a susceptor portion having a mounting surface on which a rear surface of the seed substrate is to be mounted, and a guide portion disposed on the susceptor portion in a state of surrounding the seed substrate,
the mounting unit is configured such that a first interval between the seed substrate and the guide portion on an upstream side in a step-flow growth direction becomes narrower than a second interval between the seed substrate and the guide portion on a downstream side in the step-flow growth direction when the epitaxial layer is grown, and
the guide portion is configured such that a temperature of the guide portion becomes lower than a temperature of the seed substrate when the epitaxial layer is grown.

2. The silicon carbide wafer manufacturing apparatus according to claim 1, wherein
the guide portion has a higher emissivity than the seed substrate,
the heating device includes a first heating device configured to heat the rear surface of the seed substrate, and a second heating device configured to heat the front surface of the seed substrate, and
the first heating device and the second heating device are configured to be driven in such a manner that a temperature of the rear surface becomes higher than a temperature of the front surface.

3. The silicon carbide wafer manufacturing apparatus according to claim 1, wherein
the guide portion has a lower emissivity than the seed substrate,
the heating device includes a first heating device configured to heat the rear surface of the seed substrate, and a second heating device configured to heat the front surface of the seed substrate, and
the first heating device and the second heating device are configured to be driven in such a manner that a temperature of the front surface becomes higher than a temperature of the rear surface.

4. The silicon carbide wafer manufacturing apparatus according to claim 1, wherein
the susceptor portion is configured such that a center of the seed substrate is to be disposed upstream of a center of the susceptor portion in the step-flow growth direction when viewed in a normal direction to a plane direction of the mounting surface.

5. The silicon carbide wafer manufacturing apparatus according to claim 1, wherein
the guide portion has a cylindrical shape, has a portion whose thickness changes in a circumferential direction, and has a shape in which a position of a center of an internal space of the guide portion is different from a position of a center of the susceptor portion when viewed in a normal direction to a plane direction of the mounting surface of the susceptor portion, and
the susceptor portion is configured such that a position of a center of the seed substrate coincides with the position of the center of the susceptor portion when viewed in the normal direction to the plane direction of the mounting surface.
